(19) United States
(12) Patent Application Publication
(10) Pub. No.: US 2009/0166705 A1
(43) Pub. Date: Jul. 2, 2009

(54) NONVOLATILE SEMICONDUCTOR MEMORY DEVICE AND METHOD OF MANUFACTURING THEREOF

(75) Inventor: Takamitsu ISHIHARA, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 12/276,739

(22) Filed: Nov. 24, 2008

(30) Foreign Application Priority Data
Dec. 26, 2007 (JP) 2007-334733
Mar. 19, 2008 (JP) 2008-721081

(51) Int. Cl. H01L 29/68; H01L 21/336

(52) U.S. Cl. 257/316; 438/257; 257/E29.17; 257/E21.422

(57) ABSTRACT

In a nonvolatile semiconductor memory device, second conductivity type source and drain regions are formed separately from each other in a first conductivity type semiconductor region on a surface thereof. A second conductivity type semiconductor region is formed in the first conductivity type semiconductor region arranged between the source and drain regions and is formed separately from the source and drain regions. A first gate insulating film is formed on the semiconductor substrate arranged between the source and drain regions. A floating gate is formed on the first gate insulating film. An intermediate gate insulating film is formed on the floating gate. A control gate is formed on the floating gate over the intermediate gate insulating film.

### CROSS REFERENCE TO RELATED APPLICATION

This application is based upon and claims the benefit of priority from the prior Japanese Patent Application No. 2007-334733, filed on Dec. 26, 2007 and the prior Japanese Patent Application No. 2008-721081, filed on Mar. 19, 2008, the entire contents of which are incorporated herein by reference.

### FIELD OF THE INVENTION

The present invention relates to nonvolatile semiconductor memory devices and methods of manufacturing thereof.

### DESCRIPTION OF THE BACKGROUND

NOR flash memories have a plurality of NOR-structured MOS nonvolatile semiconductor memory devices. Each semiconductor memory device has a source region and a drain region formed on the semiconductor substrate surface to oppose each other, a gate insulating film sequentially stacked on a channel region arranged between the source and drain regions, a floating gate, an intermediate gate insulating film, and a control gate.

Write operations to NOR flash memories are performed by applying ground to the source region, and applying predetermined voltages to the control gate and the drain region, respectively. For example, a voltage of 12 V is applied to the control gate, and 3.5 V to the drain region. This creates a high electrical field at the edge of the drain region. The high electrical field leads to accelerate channel current to high energy and create hot electrons. The hot electrons are injected into the floating gate.

The application of high voltage to the drain region degrades the gate insulating film adjacent to the drain region. A reduction of the gate length causes the deterioration of the write characteristics. For example, problems and solutions for the miniaturization of the NOR flash memories are disclosed in Nihar R. Mohapatra, Deep R. Nair, S. Mahapatra, V. Ramgopal Rao, S. Shukuri, and Jeff D. Bude; “CHISEL Programming Operation of Scaled NOR Flash EEPROMs-Effect of Voltage Scaling, Device Scaling and Technological Parameters”, IEEE TRANSACTIONS ON ELECTRON DEVICES, October 2003, vol. 50, No. 10, p.2104-2111. Mohapatra et al. describes the effect of channel induced secondary electrons on the write characteristics. For example, the deterioration due to the scaling (miniaturization), the optimization of the device parameter, and a trade-off for the problem of the drain edge are described.

NOR flash memories implement the write operations using the high energy hot electrons. For this reason, it is essential to guarantee reliability and to reduce a supply voltage associate with the scaling of the device structure. Since the amount of hot electron generation depends on the magnitude of supply voltage, the reduction of the supply voltage leads to degradation of the write characteristics.

NOR flash memories (hereinafter, referred to as “B4 flash memories”) which use a writing method called Back Bias Assisted Band-to-Band Tunneling Induced Hot-Electron Injection, is disclosed in Shoji Shukuri, Natsuo Ajika, Masaaki Mihara, Kazuo Kobayashi, Tetsuo Endoh and Moriyoshi Nakashima; “A 60 nm NOR Flash Memory Cell Technology Utilizing Back Bias Assisted Band-to-Band Tunneling Induces Hot-Electron Injection (B4-Flash),” 2006 Symposium On VLSI Technology Technical Papers, p. 20-21. The NOR flash memories disclosed by Shukuri et al. reduce the magnitude of the supply voltage and improve the write characteristics.

B4-flash memories, unlike conventional NOR flash memories, supply voltage V_{sub} and have a low-level of the drain voltage V_{d} when writing information. For example, the control gate voltage of V_{cg}=12 V, the substrate voltage of V_{sub}=4 V, and the drain voltage of V_{d}=−1.8 V are applied in a case that the semiconductor substrate is an n type semiconductor substrate and the source and drain regions are p type semiconductor regions. In B4-flash memories, a write operation is implemented by injecting hot electrons generated by Band-to-Band Tunneling (hereinafter, referred to as a “BBT”), which is generated by the high electrical field at the edge of the drain region, into the floating gate. As a result, the damage to the gate insulating film adjacent to the drain region is reduced, and therefore the deterioration of the insulating film is suppressed. The hot electrons generated by the BBT have a very high energy, allowing more efficient writing to the floating gate.

B4-flash memories can decrease the supply voltage and improve the write characteristics compared to the conventional NOR flash memories. In addition, B4-flash memories realize low power consumption because the channel current does not flow, different from the conventional NOR flash memories.

In the B4-flash memory, the increase in the electric field applied to the gate insulating film and the increase in the generation amount of the hot electrons due to the enhancement of the generation efficiency of the BBT enhance the writing efficiency. The electric field applied to the gate insulating film is proportional to V_{FG}-V when a surface potential of the semiconductor substrate between the source and drain regions is V and the potential of the floating gate is V_{FG}. It is necessary to decrease the surface potential of the semiconductor substrate between the source and drain regions to increase the electric field applied to the gate insulating film without changing the magnitude of the applied voltage and the potential V_{FG} of the floating gate.

The generation rate of the BBT virtually depends on the intensity of the electric field at the edge of the drain region in the gate length direction. The intensity of the electric field Eₓ in the gate length direction roughly equals to (V−V_{d})/L where the voltage applied to the drain region is V_{d} and the gate length is L. To increase the intensity of the electric field in the direction of the gate length, it is necessary to increase a surface potential V of the semiconductor substrate between the source and the drain regions.

The electric field applied to the gate insulating film decreases and that applied in the direction of the gate length increases when the surface potential V of the semiconductor substrate between the source and the drain regions increases. In contrast, the electric field applied to the gate insulating film increases and that applied in the direction of the gate length decreases when the surface potential V of the semiconductor substrate between the source and the drain regions decreases. When the intensity of the electric field applied to the gate insulating film increases, that in the direction of the gate length decreases and vice versa. Therefore, it is difficult to increase the electric field applied to the insulating film and enhance the generation rate of BBT without changing the applied voltage in the case of the conventional B4-flash memories.

### SUMMARY OF THE INVENTION

Accordingly, an advantage of the present invention is to provide nonvolatile semiconductor memory devices which enhances the writing efficiency by increasing the electric field applied to the gate insulating film and by increasing the number of hot electrons to be generated.

In order to achieve the above-described advantage, a first aspect of the present invention is to provide A nonvolatile semiconductor memory device which comprises a semiconductor substrate having a first conductivity type semiconductor region on a surface thereof, second conductivity type source and drain regions formed separately from each other in the first conductivity type semiconductor region, a second conductivity type semiconductor region formed in the first conductivity type semiconductor region arranged between the source and drain regions, the second conductivity type semiconductor region being formed separately from the source and drain regions, a first gate insulating film formed on the semiconductor substrate arranged between the source and drain regions, a floating gate formed on the first gate insulating film, an intermediate gate insulating film formed on the floating gate, and a control gate formed on the floating gate over the intermediate gate insulating film.

In order to achieve the above-described advantage, a second aspect of the present invention is to provide A nonvolatile semiconductor memory device which comprises a semiconductor substrate having a first conductivity type semiconductor region on a surface thereof, second conductivity type source and drain regions formed separately from each other in the first conductivity type semiconductor region, a second conductivity type semiconductor region formed in the first conductivity type semiconductor region arranged between the source and drain regions, the second conductivity type semiconductor region being formed separately from the source and drain regions, a first gate insulating film formed on the semiconductor substrate arranged between the source and drain regions, a first floating gate formed between the second conductivity type semiconductor region and the source region over the first gate insulating film, a second floating gate formed between the second conductivity type semiconductor region and the drain region over the first gate insulating film, the second floating gate being formed separately from the first floating gate, an intermediate gate insulating film formed on the first and second floating gates, and a control gate formed on the first and second floating gates over the intermediate gate insulating film and formed on the second conductivity type semiconductor region over the first gate insulating film.

In order to achieve the above-described advantage, a third aspect of the present invention is to provide a nonvolatile semiconductor memory device which comprises a semiconductor substrate having a first conductivity type semiconductor region on a surface thereof, second conductivity type source and drain regions formed separately from each other in the first conductivity type semiconductor region, a second conductivity type semiconductor region formed in the first conductivity type semiconductor region arranged between the source and drain regions, the second conductivity type semiconductor region being formed separately from the source and drain regions, a first gate insulating film formed on the semiconductor substrate arranged between the source and drain regions, a first floating gate formed between the second conductivity type semiconductor region and the source region over the first gate insulating film, a second floating gate formed between the second conductivity type semiconductor region and the drain region over the first gate insulating film, the second floating gate being formed separately from the first floating gate, a first intermediate gate insulating film formed on the first floating gate, a second intermediate gate insulating film formed on the second floating gate, a second gate insulating film formed on the first gate insulating film arranged on the second conductivity type semiconductor region, and a control gate formed on the first and second floating gates over the intermediate gate insulating film and formed on the second conductivity type semiconductor region over the first and second gate insulating films.

In order to achieve the above-described advantage, a fourth aspect of the present invention is to provide a nonvolatile semiconductor memory device which comprises a semiconductor substrate having a first conductivity type semiconductor region on a surface thereof, second conductivity type source and drain regions formed separately from each other in the first conductivity type semiconductor region, a second conductivity type semiconductor region formed in the first conductivity type semiconductor region arranged between the source and drain regions, the second conductivity type semiconductor region being formed separately from the source and drain regions, a first gate insulating film formed on the semiconductor substrate arranged between the second conductivity type semiconductor region and the source region and between the second conductivity type semiconductor region and the drain region, a first floating gate formed between the second conductivity type semiconductor region and the source region over the first gate insulating film, a second floating gate formed between the second conductivity type semiconductor region and the drain region over the first gate insulating film, the second floating gate being formed separately from the first floating gate, an intermediate gate insulating film formed on the first and second floating gates, a second gate insulating film formed on the second conductivity type semiconductor region and having a thickness no less than a thickness of the first gate insulating film, and a control gate formed on the first and second floating gates over the intermediate gate insulating film and formed on the second conductivity type semiconductor region over the second gate insulating film.

### BRIEF DESCRIPTION OF THE DRAWINGS

FIG. 1 is a cross-sectional view illustrating a device structure of a B4-flash memory according to the first embodiment of the present invention.

FIG. 2 is a schematic view illustrating a potential distribution on the surface of the semiconductor substrate of the B4-flash memory according to the first embodiment of the present invention.

FIG. 3 is a schematic view illustrating an electric field in a longitudinal direction on the surface of the semiconductor substrate of the B4-flash memory according to the first embodiment of the present invention.

FIG. 4 is a schematic view illustrating an electric field in a gate length direction on the surface of the semiconductor substrate of the B4-flash memory according to the first embodiment of the present invention.

FIGS. 5A-5H are cross-sectional views of the B4-flash memory fabricated according to the first embodiment of a method in accordance with the present invention.

FIG. 6 is a cross-sectional view illustrating a device structure of a B4-flash memory according to the second embodiment of the present invention.

FIG. 7 is a cross-sectional view illustrating a device structure of a B4-flash memory according to the third embodiment of the present invention.

FIG. 8 is a cross-sectional view illustrating a device structure of a B4-flash memory according to the fourth embodiment of the present invention.

FIGS. 9A-I are cross-sectional views of the B4-flash memory fabricated according to the fourth embodiment of a method in accordance with the present invention.

FIG. 10 is a cross-sectional view illustrating a device structure of a B4-flash memory according to a modified example of the fourth embodiment of the present invention.

FIG. 11 is a cross-sectional view illustrating a device structure of a B4-flash memory according to the fifth embodiment of the present invention.

FIGS. 12A-E are cross-sectional views of the B4-flash memory fabricated according to the fifth embodiment of a method in accordance with the present invention.

FIG. 13 is a cross-sectional view illustrating a device structure of a B4-flash memory according to the sixth embodiment of the present invention.

FIGS. 14A-G are cross-sectional views of the B4-flash memory fabricated according to the sixth embodiment of a method in accordance with the present invention.

FIG. 15 is a cross-sectional view illustrating a device structure of a B4-flash memory according to the seventh embodiment of the present invention.

FIGS. 16A-H are cross-sectional views of the B4-flash memory fabricated according to the seventh embodiment of a method in accordance with the present invention.

FIGS. 17A-D are cross-sectional views illustrating a device structure of a B4-flash memory according to the eighth embodiment of the present invention.

FIGS. 18A-D are cross-sectional views illustrating a device structure of a B4-flash memory according to the ninth embodiment of the present invention.

FIGS. 19A-D are cross-sectional views illustrating a device structure of a B4-flash memory according to the tenth embodiment of the present invention.

FIGS. 20A-H are cross-sectional views of the B4-flash memory fabricated according to the tenth embodiment of a method in accordance with the present invention.

FIGS. 21A-H are cross-sectional views of the B4-flash memory fabricated according to the tenth embodiment of a method in accordance with the present invention.

FIGS. 22A-I is a cross-sectional view of the B4-flash memory fabricated according to the tenth embodiment of a method in accordance with the present invention.

FIGS. 23A-H are cross-sectional views of the B4-flash memory fabricated according to the tenth embodiment of a method in accordance with the present invention.

### DETAILED DESCRIPTION OF THE INVENTION

Reference will now be made in detail to the present embodiments of the invention, examples of which are illustrated in the accompanying drawings. An exemplary B4-flash memory according to embodiments of the present invention will be explained in reference to the drawings as follows.

### First Embodiment

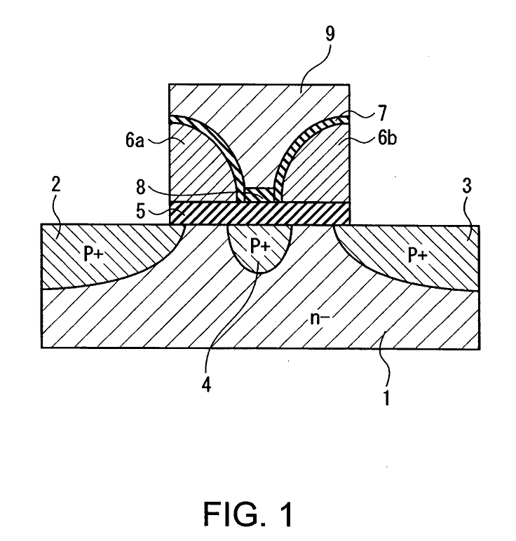

FIG. 1 is a cross-sectional view illustrating the device structure of a B4-flash memory according to a first embodiment of the present invention.

In the device structure of the B4-flash memory of this embodiment, a second conductivity type (e.g., p⁺ type) source region 2 and a drain region 3 are formed separately from each other to oppose each other in a first conductivity type (e.g., n⁻ type) semiconductor substrate 1. The superscript of n⁻ denotes a low concentration of n type impurities. The superscript of p⁺ denotes a high concentration of p⁺ type impurities. A p⁺ type impurity diffusion region 4 of the second conductivity type semiconductor region is formed separately from source region 2 and drain region 3 in semiconductor substrate 1 between source region 2 and drain region 3. A first gate insulating film 5 is formed on semiconductor substrate 1 between source region 2 and drain region 3.

Source region 2, drain region 3 and impurity diffusion region 4 are, for example, formed by boron implantation with a dopant concentration of 5×10¹⁹-1×10²⁰ cm⁻³. Source region 2, drain region 3 and impurity diffusion region 4 are, for example, formed to a depth between 120-150 nm from the surface of semiconductor substrate 1. The distance between source region 2 and impurity diffusion region 4 is formed to be, for example, 30 nm. The distance between drain region 3 and impurity diffusion region 4 is formed to be, for example, 30 nm. The width of impurity diffusion region 4 is formed to be, for example, 30 nm. First gate insulating film 5 is formed to have a thickness of, for example, 8-10 nm.

A first floating gate 6a is formed between source region 2 and impurity diffusion region 4 over or through first gate insulating film 5. First floating gate 6a is formed adjacent to the edge of source region 2 and that of impurity diffusion region 4. A second floating gate 6b is formed between drain region 3 and impurity diffusion region 4 through first gate insulating film 5. Second floating gate 6b is formed adjacent to the edge of drain region 3 and that of impurity diffusion region 4. The term “adjacent to,” as used in this specification, refers to a distance within the range where electrical charges are injected from at least one of source region 2, drain region 3 and impurity diffusion region 4 into first and second floating gates 6a, 6b.

First and second floating gates 6a, 6b are formed in a fan-like shape respectively, and are formed separately to sandwich impurity diffusion region 4. The outside sidewalls of first and second floating gates 6a, 6b are formed to have a thickness of, for example, 100 nm. The thickness of first and second floating gates 6a, 6b decreases toward the center of semiconductor substrate 1. The lengths of the bottom part of first and second floating gates 6a, 6b are formed to have a thickness of, for example, 30 nm. The distance between first and second floating gates 6a, 6b are formed to have a thickness of, for example, 30 nm.

Intermediate gate insulating film 7 is formed on first and second floating gates 6a, 6b. Intermediate gate insulating film 7 is formed to have a thickness of, for example, 15-20 nm. Intermediate gate insulating film 7 is formed between first and second floating gates 6a, 6b and control gate 9. A second gate insulating film 8 is formed on first gate insulating film 5 between intermediate gate insulating film 7 of first floating gate 6a and that of second floating gate 6b to prevent the electron injection to control gate 9 as described below. Second gate insulating film 8 has a thickness no less than a thickness of intermediate gate insulating film 7. Gate insulating film 8 is formed to have a thickness of, for example, 15-20 nm. A control gate 9 is formed on intermediate gate insulating film 7 of first and second floating gates 6a, 6b and is formed on second gate insulating film 8 located between first and second floating gates 6a, 6b. The sidewalls of control gate 9 are formed to have a thickness of, for example, 100 nm.

In the above described B4-flash memory, for example, a ground is applied to source region 2 (Vₛ=0V), a voltage of −1.8 V to drain region 3 (V_{d}=−1.8 V), a voltage of 12 V to control gate 9 (V_{cg}=12 V), a voltage of 4 V to semiconductor substrate 1 (V_{sub}=4 V) during the writing of information Each of the control gate (V_{cg}) and the semiconductor substrate (V_{sub}) is preferably greater than any of the voltages Vₛ and V_{d}. In this embodiment, V_{cg} is greater than V_{sub}.

The above described B4-flash memory according to this embodiment of the present invention may enhance the writing efficiency by increasing the electric field applied to first gate insulating film 5 and by increasing the number of hot electrons to be generated. The mechanism of the enhancement of the writing efficiency will be explained below.

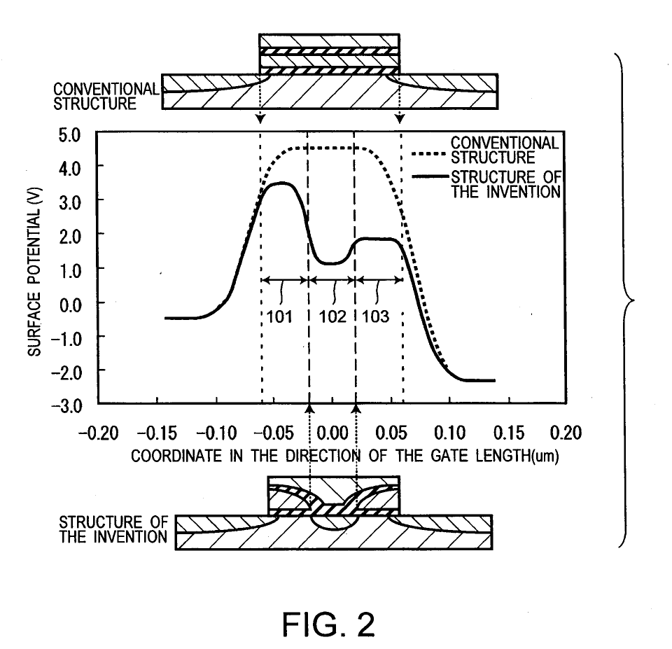

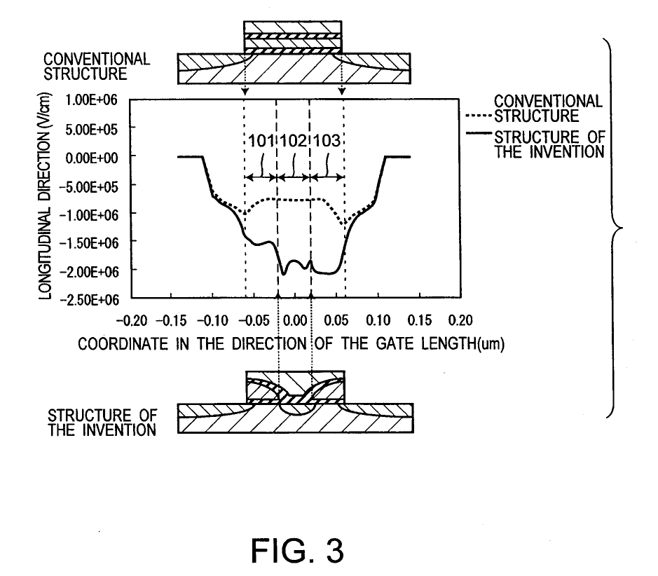

A mechanism of the increase of the electric field applied to first gate insulating film 5 will be explained. FIG. 2 is a schematic view illustrating a potential distribution of the surface of semiconductor substrate 1 during the writing of information. The horizontal axis represents the coordinate in the direction of the gate length with respect to the center of the surface of semiconductor substrate 1 located between source region 2 and drain region 3 of semiconductor substrate 1. The vertical axis represents a potential (V) of the surface of semiconductor substrate 1. In FIG. 2, a region 101 corresponds to the surface region of semiconductor substrate 1 under first floating gate 6a shown in the left side of FIG. 1. A region 102 corresponds to impurity diffusion region 4 located in the central area of the surface region of semiconductor substrate 1. A region 103 corresponds to the surface region of semiconductor substrate 1 under second floating gate 6b shown in the right side of FIG. 1. FIG. 3 is a schematic view illustrating electric field in a longitudinal direction, which is applied to first gate insulating film 5. The horizontal axis represents the coordinate in the direction of the gate length with respect to the center of the surface of semiconductor substrate 1 located between source region 2 and drain region 3 of semiconductor substrate 1. The vertical axis represents electric field in a longitudinal direction, which is applied to first gate insulating film 5. In FIGS. 2 and 3, the dashed line represents the conventional B4-flash memory and the solid line represents the B4-flash memory of this embodiment.

As shown in FIG. 2, the B4-flash memory of this present invention has smaller surface potential V of semiconductor substrate 1 across the surface of semiconductor substrate 1 between source region 2 and drain region 3 compared with the conventional B4-flash memory. Impurity diffusion region 4 strongly enhances Drain-Induced Barrier Lowering (DIBL) across the surface of semiconductor substrate 1 between source region 2 and drain region 3. This enables negative voltage applied to drain region 3 to transmit easily across the surface of semiconductor substrate 1 between source region 2 and drain region 3. As a result, the potential (V) of semiconductor substrate 1 between source region 2 and drain region 3 decreases. As shown in FIG. 3, the longitudinal electric field applied to first gate insulating film 5 of this embodiment is greater than that of conventional technology. As greater electric field is applied to first gate insulating film 5, hot electrons are easily injected into the floating gates.

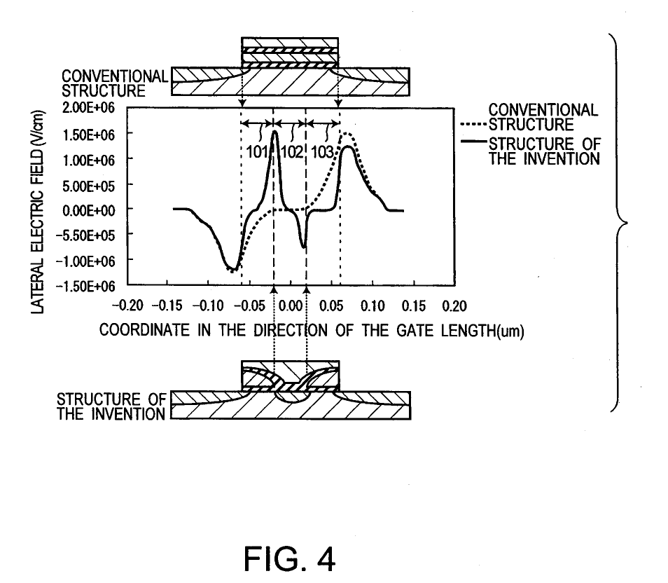

The mechanism of the increase of the hot electrons will be explained below. FIG. 4 is a schematic view illustrating the electrical field in the gate length direction at the surface of semiconductor substrate 1 between source region 2 and drain region 3. The horizontal axis represents the coordinate in the direction of the gate length with respect to the center of the surface of semiconductor substrate 1. The vertical axis represents a lateral electric field in the gate length direction. In FIG. 4, the dashed line represents the conventional B4-flash memory and the solid line represents the B4-flash memory of this embodiments.

In B4-flash memory of this embodiment, p⁺ impurity diffusion region 4 is formed between p⁺ source region 2 and drain region 3 through an n⁻ channel region, and therefore two pn junction regions are increased. A built-in potential is created in the pn junctions. The voltage V_{sub} results in the band bending of the built-in potential in the pn junction and creates a high electrical field. Thus, the structure of this embodiment creates two more high electrical field generation regions. In this embodiment, the positive voltage Vcg applied to control gate 9 acts as a reverse bias with respect to impurity diffusion region 4 (i.e., region 102). A depletion layer is then created on the surface of impurity diffusion region 4 and negative charges are generated. The surface potential of impurity diffusion region 4 (i.e., region 102) decreases, and the depletion layer generated on the surface of impurity diffusion region 4 causes regions 101 and 103 to be in an electrically floating condition. The surface potential V of regions 101 and 103 increases due to capacitance coupling with control gate 9. The potential differences between regions 101 and 102 and between regions 102 and 103 increase. Region 103 is located adjacent to drain region 3 and is strongly affected by the negative voltage applied to drain region 3. As a result, the surface potential greatly decreases as shown in FIG. 2. Region 101 is strongly affected by the capacitance coupling with control gate 9 and the decrease in the surface potential is small.

As shown in FIG. 2, there exist potential differences between regions 101 and 102 and between regions 102 and 103. These potential differences provide a high electrical field in the gate length direction between regions 101 and 102 and between regions 102 and 103. As shown in FIG. 4, in this embodiment, the relatively conventional parts (i.e., the side edge of the channel side of source region 2 and that of drain region 3) also have a high electrical field as well as the above regions. The magnitude of the high electrical field in these regions does not change, while the number of the generation points increases. As a result, the number of hot electrons to be generated increases.

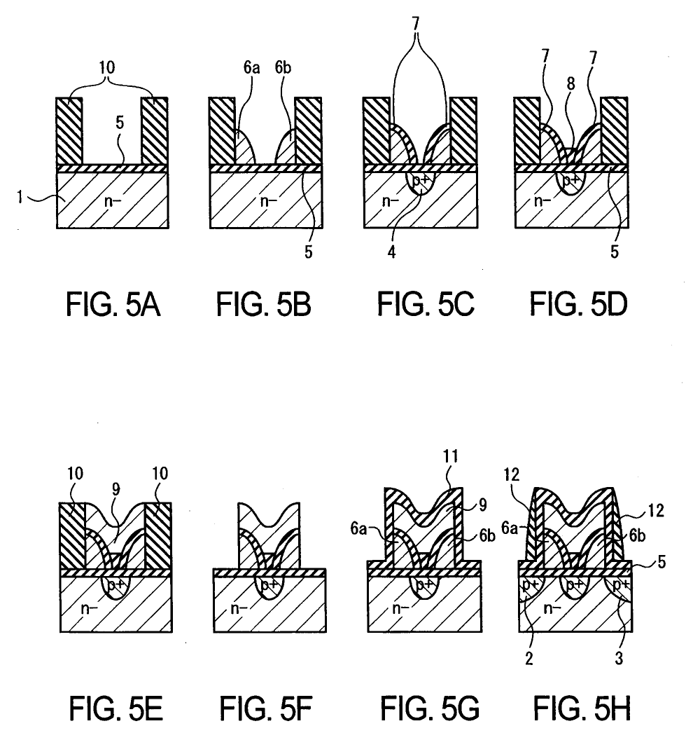

With reference to FIGS. 5A-H, a manufacturing process of the B4-flash memory of this embodiment will be explained. FIGS. 5A-H are cross-sectional views of the B4-flash memory fabricated according to this embodiment of a method in accordance with the present invention.

As shown in FIG. 5A, first gate insulating film 5 having a film thickness of 8-10 nm is formed on an entire upper surface of semiconductor substrate 1 such as an n⁻ silicon (Si) substrate 1. Gate insulating film 5 may be, for example, a silicon oxide film formed by a thermal oxidation. An insulating film (e.g., a silicon nitride film) having an etching selectivity different from first gate insulating film 5 is formed on an entire upper surface of first gate insulating film 5. The insulating film is then patterned with photolithography to cover first gate insulating film 5 on regions where source region 2 and drain region 3 will be formed and to form first insulating film pattern 10 for exposing first gate insulating film 5 under regions where first and second floating gates 6a and 6b will be formed and on a region where impurity diffusion region 4 will be formed.

As shown in FIG. 5B, a polycrystalline silicon film is deposited on first gate insulating film 5 by, for example, an LPCVD (Low Pressure Chemical Vapor Deposition) method. Fan-like first and second floating gates 6a and 6b are then formed respectively by etching the polycrystalline silicon film. The sidewalls of first and second floating gates 6a and 6b are formed to be in contact with the sidewall of first insulating film pattern 10 so as to sandwich the region where impurity diffusion region 4 will be formed. The bottom of first and second floating gates 6a and 6b are formed to be, for example, 30 nm. The distance between first and second floating gates 6a and 6b are formed to be, for example, 30 nm.

As shown in FIG. 5C, an intermediate gate insulating film material is formed by, for example, CVD method so as to cover first and second floating gates 6a and 6b. An intermediate gate insulating film 7 are formed respectively by photolithography. Intermediate gate insulating film 7 may be, for example, an ONO film or a high-dielectric insulating film such as alumina.

Boron (B) is ion-implanted into the surface region of n⁻ silicon substrate 1 sandwiched between first and second floating gates 6a and 6b using first and second floating gates 6a and 6b with intermediate gate insulating film 7 as a mask. This allows p⁺ impurity diffusion region 4 to have a concentration of 5×10¹⁹-1×10²⁰ cm⁻³ and to have a depth of 120-150 nm.

As shown in FIG. 5D, an insulating film is formed on intermediate gate insulating film 7 and first gate insulating film 5. Second gate insulating film 8 is then formed on first gate insulating film 5 sandwiched between intermediate gate insulating film 7 of first and second floating gates 6a and 6b by an etching process. Second gate insulating film 8 is formed to be, for example, 15-20 nm and may be formed by a silicon oxide film.

As shown in FIG. 5E, a polycrystalline silicon is deposited on intermediate gate insulating film 7 of first and second floating gates 6a and 6b, and is deposited on second gate insulating film 8 located between first and second floating gates 6a and 6b by, for example, an LPCVD method, and is patterned with photolithography to form control gate 9.

As shown in FIG. 5F, first insulating film pattern 10 is removed by an etching process. As shown in FIG. 5G, a gate protection insulating film 11 is formed to cover the stacked gate structure comprising first and second floating gates 6a and 6b, intermediate gate insulating film 7 and control gate 9. G ate protection insulating film 11 may be formed by, for example, a silicon oxide.

As shown in FIG. 5H, an insulating film is deposited and a sidewall insulating film 12 is then formed on gate protection insulating film 11 by etching the insulating film. The resultant sidewall insulating film 12 is formed by, for example, TEOS. Boron (B) is ion-implanted into the surface region of n⁻ silicon substrate 1 located outside of first and second floating gates 6a and 6b using the stacked structure as a mask. As a result, a p⁺ source region 2 is formed in the left side region of first floating gate 6a, and a p⁺ drain region 3 is formed in the right side region of second floating gate 6b. p⁺ source region 2 and p⁺ drain region 3 are formed to have a concentration of 5×10¹⁹-1×10²⁰ cm⁻³ and to have a depth of 120-150 nm. The B4-flash memory as shown in FIG. 1 is fabricated by the above manufacturing process.

As described above, according to the first embodiment, impurity diffusion region 4 formed between source region 2 and drain region 3 may enhance the writing efficiency by increasing the electric field applied to gate insulating film 5 and by increasing the number of hot electrons to be generated.

Further, according to the first embodiment, first floating gate 6a is formed between impurity diffusion region 4 and source region 2, and second floating gate 6b is formed between impurity diffusion region 4 and drain region 3. Control gate 9 is formed on first and second floating gates 6a and 6b through intermediate gate insulating film 7, and is formed on impurity diffusion region 4 located between first and second floating gates 6a and 6b through first and second gate insulating films 5 and 8. Impurity diffusion region 4 is strongly affected by control gate 9, and therefore a depletion layer is easily generated on the surface of impurity diffusion region 4. This enhances the generation rate of BBT and increases the number of hot electrons to be generated and improves the writing efficiency. Control gate 9 is formed between first and second floating gates 6a and 6b to be in contact with intermediate gate insulating film 7 of first and second floating gates 6a and 6b. The increase of the capacity ratio of intermediate gate insulating film 7 relative to first gate insulating film 5 and the electric field applied to first gate insulating film 5 improves the writing efficiency. Therefore, the writing efficiency may be improved by the increase of the electric field applied to gate insulating film 5 and the number of hot electrons to be generated.

Second gate insulating film 8 formed between control gate 9 and first gate insulating film 5 caused the distance between control gate 9 and semiconductor substrate 1 to be greater. This prevents the unwanted injection of the electrons from impurity diffusion region 4 into control gate 9.

In addition, first and second floating gates 6a and 6b can be used as a mask during boron ion-implantation for the formation of impurity diffusion region 4. Therefore, the manufacturing process becomes easier.

### Second Embodiment

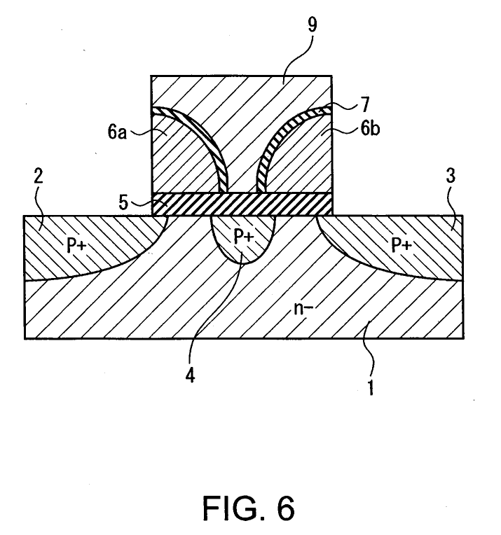

FIG. 6 is a cross-sectional view of a B4-flash memory device according to a second embodiment of the present invention. In this embodiment, the structure of the B4-flash memory device is similar to that in the first embodiment, except that a control gate 9 is directly formed on first gate insulating film 5 located between first and second floating gate regions 6a and 6b without second gate insulating film 8.

The manufacturing process of the B4-flash memory device of this embodiment is similar to that of the first embodiment, except that second gate insulating film 8 is not formed on first gate insulating film 5 located between first and second floating gate regions 6a and 6b.

According to this embodiment, as similar to the first embodiment, the writing efficiency may be improved by increasing the electric field applied to first gate insulating film 5 and by increasing the number of hot electrons to be generated. In addition, the manufacturing process becomes easier.

### Third Embodiment

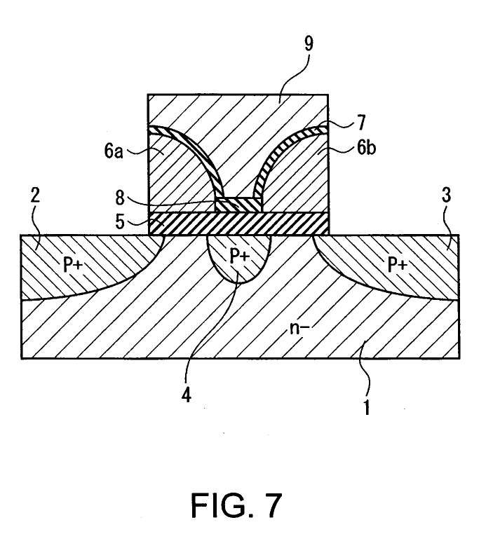

FIG. 7 is a cross-sectional view of a B4-flash memory device according to a third embodiment of the present invention. In this embodiment, the structure of the B4-flash memory device is similar to that in the first embodiment, except that the side edge of second gate insulating film 8 reaches the surface of first and second floating gates 6a and 6b, and that of intermediate gate insulating film 7 is formed on second gate insulating film 8.

The manufacturing process of the B4-flash memory device of this embodiment is similar to that of the first embodiment, except that the process sequence of the formation step of intermediate gate insulating film 7 of FIG. 5C and that of second gate insulating film 8 of FIG. 5D is opposite.

According to this embodiment, similar to the first embodiment, the writing efficiency may be improved by increasing the electric field applied to first gate insulating film 5 and by increasing the number of hot electrons to be generated. In addition, the unwanted injection of the electrons from impurity diffusion region 4 into control gate 9 may be prevented and the manufacturing process becomes easier.

### Fourth Embodiment

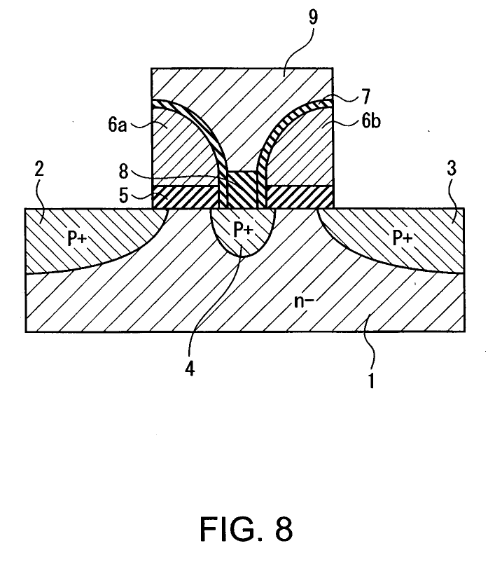

FIG. 8 is a cross-sectional view of a B4-flash memory device according to a third embodiment of the present invention. In this embodiment, the structure of the B4-flash memory device is similar to that in the first embodiment, except that gate insulating film 5 is formed only under first and second floating gates 6a and 6b, and intermediate gate insulating film 7 is formed on first and second floating gates 6a and 6b and is formed on the side of first gate insulating film 5, and second gate insulating film 8 is formed on n⁻ silicon (Si) substrate 1 located between intermediate gate insulating film 7 formed on floating gates 6a and 6b.

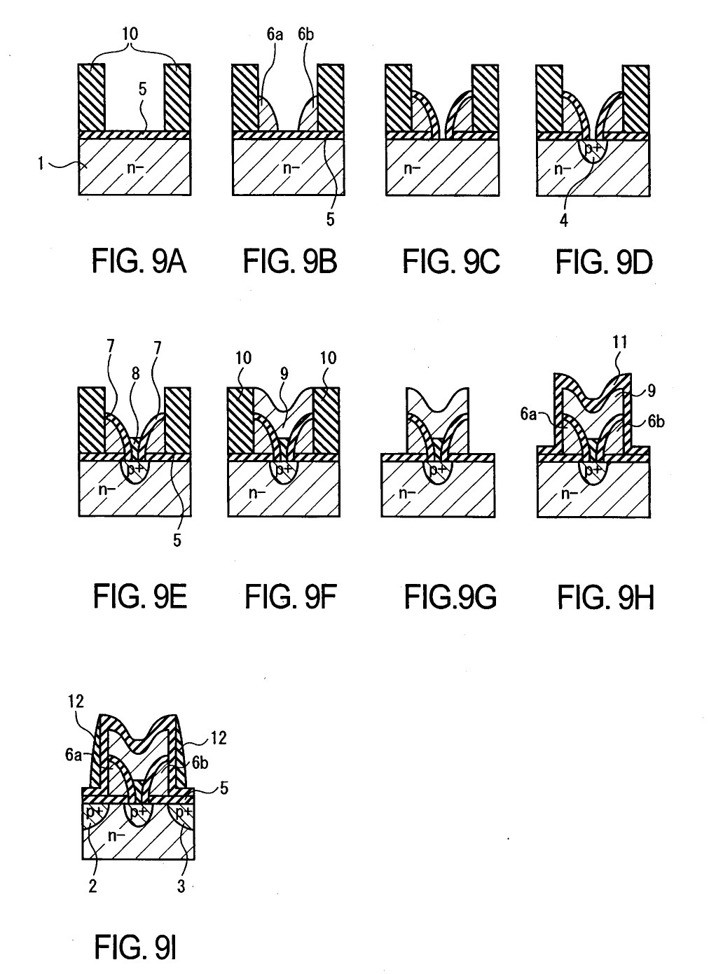

With reference to FIGS. 9A-I, a manufacturing process of the B4-flash memory of this embodiment will be explained since the manufacturing process of this embodiment is different from that of the first embodiment. FIGS. 9A-I are cross-sectional views of the B4-flash memory fabricated according to this embodiment of a method in accordance with the present invention.

As shown in FIG. 9A, first gate insulating film 5 is formed on an entire upper surface of semiconductor substrate 1 (e.g., an n⁻ silicon (Si) substrate). Gate insulating film 5 may be, for example, a silicon oxide film. An insulating film such as a silicon nitride film having an etching selectivity different from first gate insulating film 5 is formed on an entire upper surface of first gate insulating film 5. The insulating film is then patterned with photolithography to cover first gate insulating film 5 on regions where source region 2 and drain region 3 will be formed, and to form first insulating film pattern 10 for exposing first gate insulating film 5 under regions where first and second floating gates 6a and 6b are formed and on a region where impurity diffusion region 4 will be formed.

As shown in FIG. 9B, a polycrystalline silicon film is deposited on first gate insulating film 5 by, for example, an LPCVD method. Fan-like first and second floating gates 6a and 6b are then formed respectively by etching the polycrystalline silicon film. The sidewalls of first and second floating gates 6a and 6b are formed to be in contact with the sidewall of first insulating film pattern 10 so as to sandwich the region where impurity diffusion region 4 will be formed.

As shown in FIG. 9C, n⁻ silicon substrate 1 located between first and second floating gates 6a and 6b is exposed by etching first gate insulating film 5 located between first and second floating gate 6a and 6b. Intermediate gate insulating film 7 are formed respectively by a CVD method and photolithography so as to cover the top of first and second floating gates 6a and 6b and the side of first gate insulating film 5. Intermediate gate insulating film 7 may be, for example, an ONO film or a high-dielectric insulating film such as alumina.

As shown in FIG. 9D, boron (B) is ion-implanted into the surface region of n⁻ silicon substrate 1 sandwiched between first and second floating gates 6a and 6b using first and second floating gates 6a and 6b with intermediate gate insulating film 7 as a mask. p⁺ impurity diffusion region 4 is then formed.

As shown in FIG. 9E, an insulating film is formed on intermediate gate insulating film 7 and n⁻ silicon substrate 1. Second gate insulating film 8 is then formed on impurity diffusion region 4 sandwiched between intermediate gate insulating film 7 formed on first and second floating gates 6a and 6b by an etching process. Second gate insulating film 8 may be, for example, a silicon oxide film. The film thickness of second gate insulating film 8 is formed to be no less than that of first gate insulating film 5 (e.g., 23-30 nm). This prevents the unwanted injection of the carriers from impurity diffusion region 4 into control gate 9.

As shown in FIG. 9F, a polycrystalline silicon is deposited on intermediate gate insulating film 7 and second gate insulating film 8 by, for example, an LPCVD method. The polycrystalline silicon is then is patterned with photolithography to form control gate 9 on intermediate gate insulating film 7 of first and second floating gates 6a and 6b, and on gate insulating film 8 located between first and second floating gates 6a and 6b.

As shown in FIG. 9G, first insulating film pattern 10 is removed by an etching process. As shown in FIG. 9H, a gate protection insulating film 11 is formed to cover the stacked gate structure comprising first and second floating gates 6a and 6b, intermediate gate insulating film 7 and control gate 9. Gate protection insulating film 11 may be formed by, for example, a silicon oxide.

As shown in FIG. 91, an insulating film is deposited and a sidewall insulating film 12 is then formed on gate protection insulating film 11 with a stacked gate structure by etching the insulating film. Resultant sidewall insulating film 12 may be formed by, for example, TEOS.

Boron (B) is ion-implanted into the surface region of n⁻ silicon substrate 1 located outside of first and second floating gates 6a and 6b using the stacked structure as a mask. As a result, a p⁺ source region 2 is formed in the left side region of first floating gate 6a, and a p⁺ drain region 3 is formed in the right side region of second floating gate 6b. The B4-flash memory as shown in FIG. 8 is fabricated by the above manufacturing process.

According to this embodiment, similar to the first embodiment, the writing efficiency may be improved by increasing the electric field applied to the first gate insulating film 5 and by increasing the number of hot electrons to be generated. In addition, the unwanted injection of the electrons from impurity diffusion region 4 into control gate 9 may be prevented and the manufacturing process becomes easier.

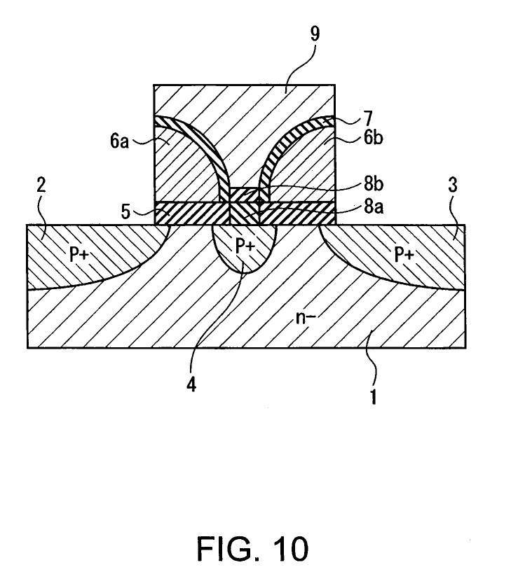

In this embodiment, second gate insulating film 8, which is formed on n⁻ silicon substrate 1 located between intermediate gate insulating film 7 of first and second floating gates 6a and 6b, is a single layer but may be formed as a stacked structure of plurality of gate insulating films. For example, as shown in FIG. 10, second gate insulating film 8 may be a stacked structure comprising, for example, a silicon oxide film, second gate insulating films 8a and 8b formed by a silicon nitride film. In this embodiment, the edge of intermediate gate insulating film 7 is formed in contact with the top of n⁻ silicon substrate 1. However, the edges of intermediate gate insulating film 7 may be formed on first gate insulating film 5 as shown in FIG. 10.

### Fifth Embodiment

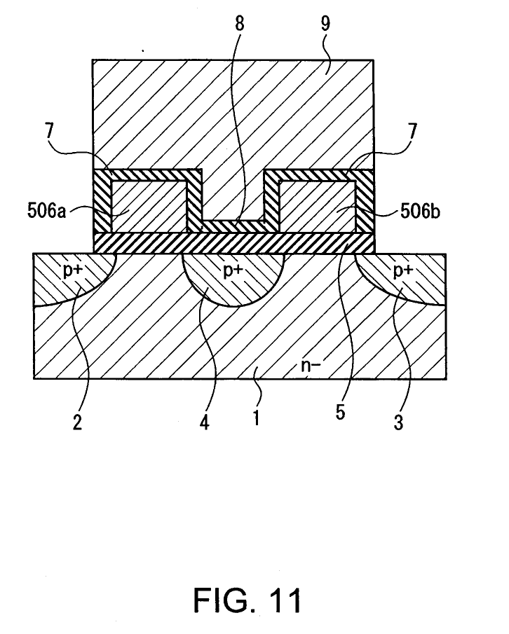

FIG. 11 is a cross-sectional view of a B4-flash memory device according to a fifth embodiment of the present invention. In this embodiment, the structure of the B4-flash memory device is substantially the same as that in the first embodiment, except that first and second floating gates 506a and 506b has a rectangular shape.

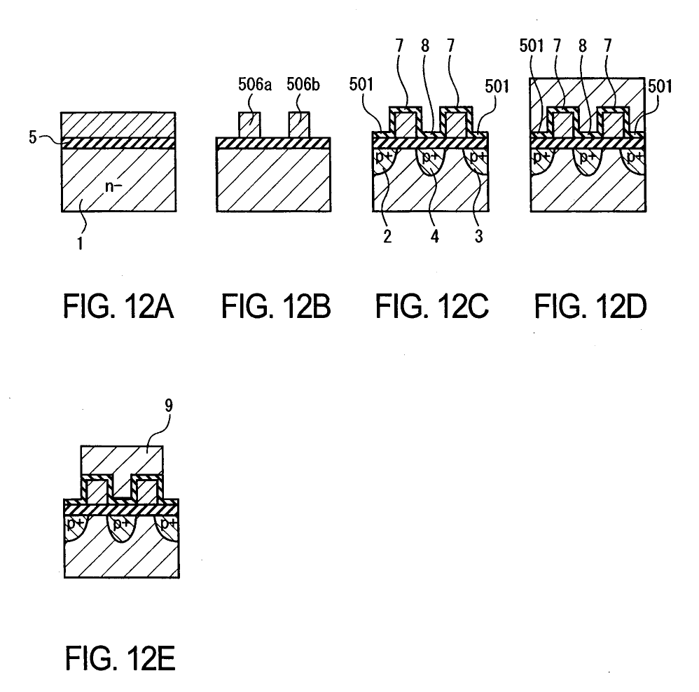

With reference to FIGS. 12A-E, a manufacturing process of the B4-flash memory of this embodiment will be explained since the manufacturing process of this embodiment is different from that of the first embodiment. As shown in FIG. 12A, first gate insulating film 5 such as a silicon oxide film is formed on an entire upper surface of a semiconductor substrate such as an n⁻ silicon (Si) substrate 1. A polycrystalline silicon is deposited on an entire upper surface of first gate insulating film 5 by, for example, an LPCVD method. As shown in FIG. 12B, first and second floating gates 506a and 506b are then patterned by photolithography to form first and second floating gates 506a and 506b having the same rectangular shape. First and second floating gates 506a and 506b are formed to expose first gate insulating film 5 on regions where source region 2 and drain region 3 will be formed and on a region where impurity diffusion region 4 will be formed.

As shown in FIG. 12C, an ONO film is deposited by, for example, a CVD method to form intermediate gate insulating film 7 covering first and second floating gates 506a and 506b, and to form second gate insulating film 8 on the first gate insulating film located between first and second floating gates 506a and 506b. Insulating film 501 is formed on first gate insulating film 5 of first floating gate 506a located on the left side of FIG. 12C (hereinafter, “left side”), and is formed on first gate insulating film 5 of second floating gate 506b located on the right side of FIG. 12C (hereinafter, “right side”). Intermediate gate insulating film 7 consists of an ONO film formed on the top of first and second floating gates 506a and 506b and on the inner side surface of first and second floating gates 506a and 506b. First and second floating gates 506a and 506b with intermediate gate insulating film 7 is used as a mask and boron (B) or the like is ion-implanted. p⁺ impurity diffusion region 4 is formed on the surface region of n⁻ silicon (Si) substrate 1 sandwiched between first and second floating gates 506a and 506b. In addition, p⁺ source region 2 is formed on the surface region of n⁻ silicon (Si) substrate 1 located on the left side of first floating gate 506a, and p⁺ drain region 3 is formed on the surface region of n⁻ silicon (Si) substrate 1 located on the right side of second floating gate 506b.

As shown in FIG. 12D, a polycrystalline silicon is deposited on intermediate gate insulating film 7, second gate insulating film 8 and insulating film 501 by, for example, an LPCVD method. As shown in 12E, the polycrystalline silicon is then patterned with photolithography to form control gate 9. Control gate 9 is formed on first and second floating gates 506a and 506b, and is formed on first gate insulating film 5 therebetween through intermediate gate insulating film 7 and second gate insulating film 8. The B4-flash memory as shown in FIG. 11 is fabricated by the above manufacturing process.

According to this embodiment, as similar to the first embodiment, the writing efficiency may be improved by increasing the electric field applied to first gate insulating film 5 and by increasing the number of hot electrons to be generated. In addition, the unwanted injection of the electrons from impurity diffusion region 4 into control gate 9 may be prevented, and the manufacturing process may be simplified by forming source region 2, drain region 3 and impurity diffusion region 4 concurrently using first and second floating gates 506a and 506b as a mask.

### Sixth Embodiment

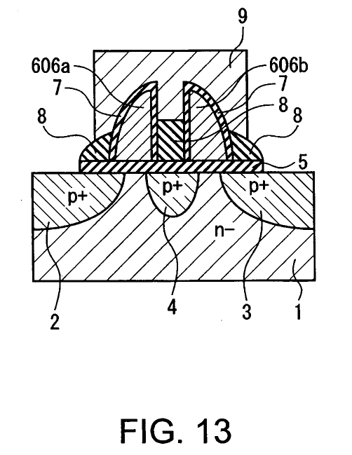

FIG. 13 is a cross-sectional view of a B4-flash memory device according to a sixth embodiment of the present invention. In this embodiment, the structure of the B4-flash memory device is substantially the same as that of the first embodiment, except that fan-like first and second floating gates 606a and 606b are reversed left to right with respect to the fan-like floating gate of the first embodiment, centering around a perpendicular direction to the semiconductor substrate.

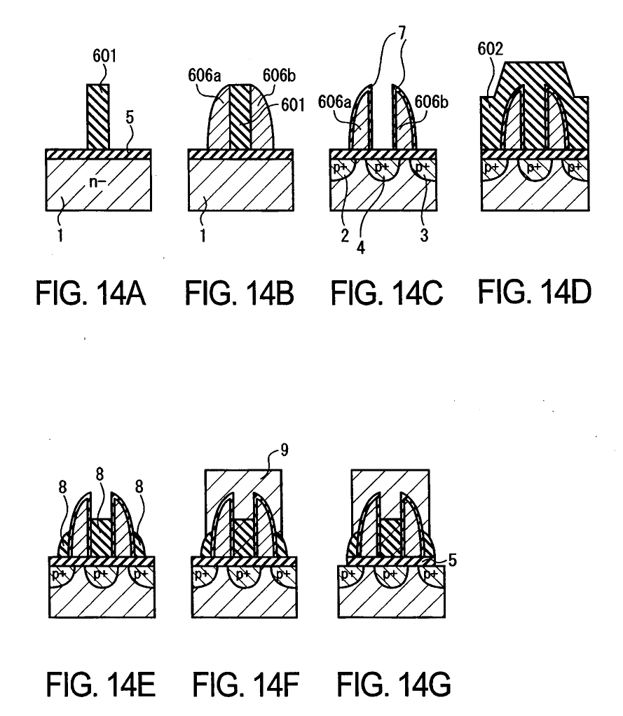

With reference to FIGS. 14A-G, a manufacturing process of the B4-flash memory of this embodiment will be explained since the manufacturing process of this embodiment is different from that of the first embodiment.

As shown in FIG. 14A, first gate insulating film 5 is formed on an entire upper surface of semiconductor substrate 1 such as an n⁻ silicon (Si) substrate. Gate insulating film 5 may be, for example, a silicon oxide film. An insulating film having an etching selectivity different from first gate insulating film 5 is formed on an entire upper surface of first gate insulating film 5. Such an insulating film may be, for example, a silicon nitride film. The insulating film is then patterned with photolithography to form second insulating film pattern 601 in a rectangular form. Second insulating film pattern 601 is formed to cover first gate insulating film 5 on a region where impurity diffusion region 4 will be formed, and to expose first gate insulating film 5 under regions where first and second floating gates 606a and 606b are formed and on regions where source region 2 and drain region 3 will be formed.

As shown in FIG. 14B, a polycrystalline silicon is deposited on first gate insulating film 5 having second insulating film pattern 601 by, for example, an LPCVD method. Fan-like shaped first and second floating gates 606a and 606b are then formed on both sidewalls of second insulating film pattern 601 respectively by etching the polycrystalline silicon. The sidewalls of first and second floating gates 606a and 606b are formed to be in contact with the sidewall of second insulating film pattern 601.

As shown in FIG. 14C, second insulating film 601 is removed by an etching process. Intermediate gate insulating film 7 is patterned by, for example, oxidation and deposition and photolithography to form intermediate gate insulating film 7 covering first and second floating gates 606a and 606b. Intermediate gate insulating film 7 has an ONO film formed on first and second floating gates 606a and 606b and on the inner side surface of first and second floating gates 606a and 606b. First and second floating gates 606a and 606b with intermediate gate insulating film 7 is used as a mask and boron (B) or the like is ion-implanted. p⁺ impurity diffusion region 4 is formed on the surface region of n⁻ silicon (Si) substrate 1 sandwiched between first and second floating gates 606a and 606b. Source region 2 is formed on the surface region of n⁻ silicon (Si) substrate 1 located on the left side of first floating gate 606a. Drain region 3 is formed on the surface region of n⁻ silicon (Si) substrate 1 located on the right side of second floating gate 606b.

As shown in FIG. 14D, insulating film 602 is formed on first gate insulating film 5 having first and second floating gates 606a and 606b. Insulating film 602 may be a silicon nitride film. As shown in FIG. 14E, second gate insulating film 8 are formed on first gate insulating film 5 in a region sandwiched between first and second floating gates 606a and 606b, in a region on the left side of first floating gate 606a, and in a region on the right side of second floating gate 606b.

A polycrystalline silicon is then deposited on second gate insulating film 8 and intermediate gate insulating film 7 by, for example, an LPCVD method. As shown in FIG. 14F, the polycrystalline silicon is then patterned with photolithography to form control gate 9 on second gate insulating film 8 and intermediate gate insulating film 7. As shown in FIG. 14G, first gate insulating film 5 and second gate insulating film 8 are removed by an etching process using second gate insulating film 8 as a mask except surface of source region 2 and drain region 3 covered by second gate insulating film 8 to expose the surface region of source region 2 and drain region 3. The B4-flash memory as shown in FIG. 13 is fabricated by the above manufacturing process.

According to this embodiment, as similar to the first embodiment, the writing efficiency may be improved by increasing the electric field applied to first gate insulating film 5 and by increasing the number of hot electrons to be generated. In addition, the unwanted injection of the electrons from impurity diffusion region 4 into control gate 9 may be prevented. The manufacturing process may be simplified by forming source region 2, drain region 3 and impurity diffusion region 4 concurrently using first and second floating gates 606a and 606b as a mask.

According to this embodiment, in addition to the effect of the first embodiment, second data insulating film 8 is formed on the edge of source region 2 and drain region 3 adjacent to first and second floating gates 606a and 606b as well as the region sandwiched by first and second floating gates 606a and 606b. This prevents the unwanted injection of the carriers from source region 2 and drain region 3 into control gate 9.

### Seventh Embodiment

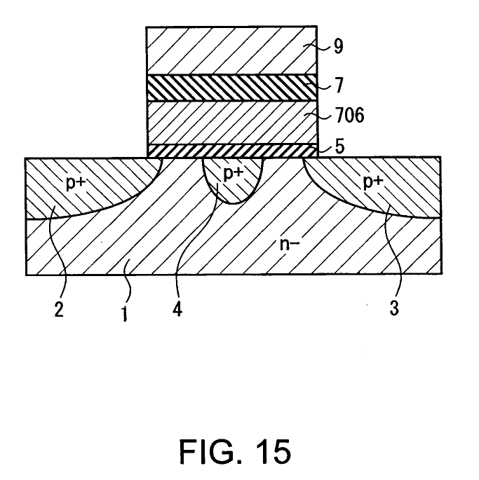

FIG. 15 is a cross-sectional view of a B4-flash memory device according to a seventh embodiment of the present invention. In this embodiment, the structure of the B4-flash memory device is substantially the same as that in the first embodiment, except that the floating gate is a single floating gate, while the floating gate of the first embodiment is formed as divided first and second floating gates.

In this embodiment, p⁺ source region 2 and drain region 3 are formed separately from each other in a semiconductor substrate such as an n⁻ silicon (Si) substrate 1. p⁺ impurity diffusion region 4 is formed between source region 2 and drain region 3. Floating gate 706, intermediate gate insulating film 7 and control gate 9 are stacked on the n⁻ silicon (Si) substrate located between source region 2 and drain region 3 through first gate insulating film 5 such that the edges of them are adjacent to the edge of source region 2 and drain region 3.

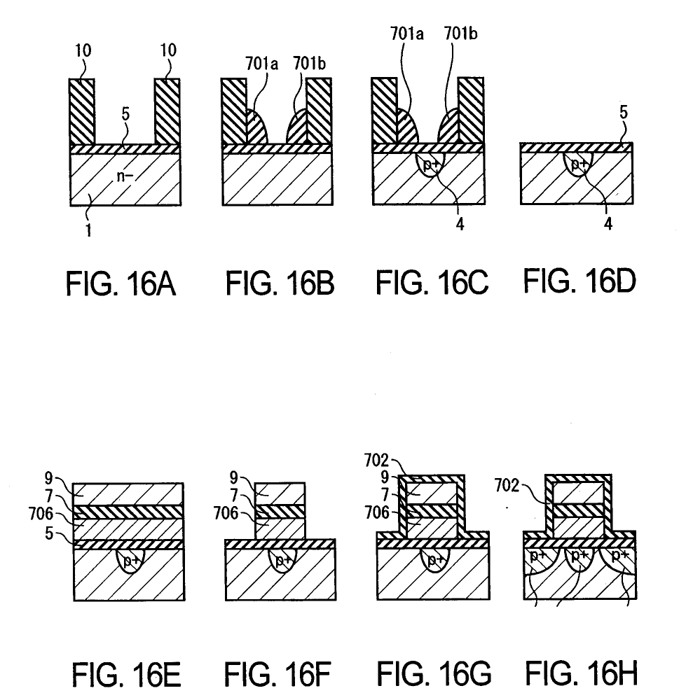

With reference to FIGS. 16A-H, a manufacturing process of the B4-flash memory of this embodiment will be explained.

As shown in FIG. 16A, first gate insulating film 5 such as a silicon oxide film is formed on an entire surface of n⁻ silicon substrate 1. First insulating film pattern 10 is formed to cover first gate insulating film 5 on regions where source region 2 and drain region 3 will be formed and to expose first gate insulating film 5 on a region where impurity diffusion region 4 will be formed. first insulating film pattern 10 is formed by an insulating film having an etching selectivity different from first gate insulating film 5 (e.g., silicon nitride film).

As shown in FIG. 16B, a third insulating film is deposited by a CVD method and is etched to form third insulating film pattern 701 on first gate insulating film 5 and the inner wall of first insulating film pattern 10. Third insulating film pattern 701 is formed by two insulating film patterns 701a and 701b. Two insulating film patterns 701a and 701b are formed in a fan-like form. The sidewalls of insulating film patterns 701a and 701b are formed to be in contact with the inner wall of first insulating film pattern 10 to sandwich a region where impurity diffusion region 4 will be formed. Third insulating film pattern 701 may be formed by an insulating film having an etching selectivity different from first insulating pattern 10 (e.g., TEOS).

As shown in FIG. 16C, boron (B) is ion-implanted into the surface region of n⁻ silicon substrate 1 sandwiched between third insulating film patterns 701a and 701b to form p⁺ impurity diffusion region 4 using third insulating film pattern 701 as a mask. As shown in FIG. 16D, first insulating film pattern 10 and third insulating film patterns 701a, 701b are removed by an etching process.

As shown in FIG. 16E, a polycrystalline silicon which will be floating gate 706, an insulating film which will be intermediate gate insulating film 7 such as an ONO film, and a polycrystalline silicon which will be a control gate 9 are stacked on an entire upper surface of first gate insulating film 5.

As shown in FIG. 16F, the stacked layers are patterned with photolithography and to form a stacked gate structure comprising floating gate 706, intermediate gate insulating film 7 and control gate 9 and to expose first gate insulating film 5 on regions where source region 2 and drain region 3 will be formed. As shown in FIG. 16G, gate protection insulating film 702 is formed by, for example, a silicon oxide to cover the surface of the stacked gate structure and exposed first gate insulating film 5.

As shown in FIG. 16H, boron (B) is ion-implanted into the surface region of n⁻ silicon substrate 1 in the left side of the stacked gate structure to form source region 2, and the surface region of n⁻ silicon substrate 1 in the right side of the stacked gate structure to form drain region 3. The B4-flash memory as shown in FIG. 15 is fabricated by the above manufacturing process.

As described above, the writing efficiency is improved by increasing the electric field applied to gate insulating film 5 and by increasing the number of hot electrons to be generated.

### Eighth Embodiment

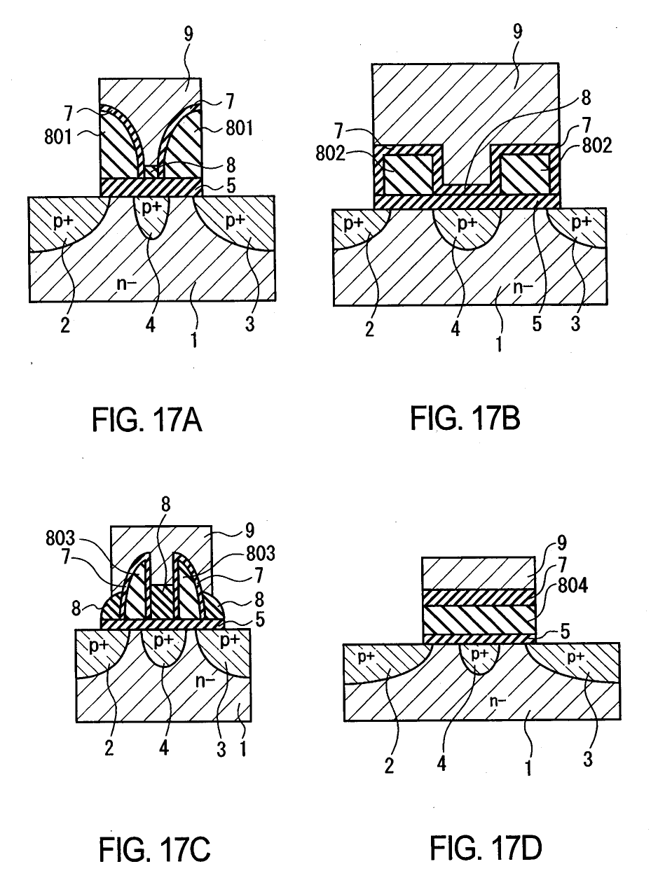

FIGS. 17A-D are cross-sectional views of a B4-flash memory device according to an eighth embodiment of the present invention. In this embodiment, the structure of the B4-flash memory device is similar to that in the first, fifth, sixth and seventh embodiments, except that floating gates 6a, 6b, 506a, 506b, 606a, 606b, 706 are replaced with charge accumulation layers 801, 802, 803 and 804, respectively. Charge accumulation layers 801, 802, 803 and 804 may be, for example, a silicon nitride film or a high-dielectric insulating film such as alumina.

The manufacturing process of the B4-flash memory device of this embodiment is similar to that in the first, fifth, sixth and seventh embodiments, except that the floating gates are replaced with a charge accumulation layer such as a nitride film or a high-dielectric insulating film.

In this embodiment, the similar effect may be obtained as in the first, fifth, sixth and seventh embodiments.

### Ninth Embodiment

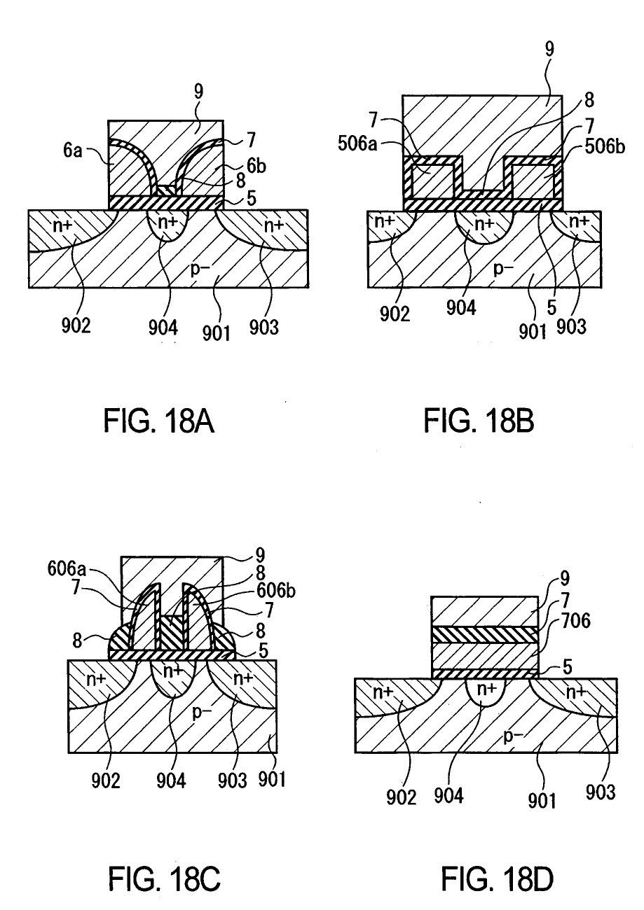

FIGS. 18A-D are cross-sectional views of a B4-flash memory device according to a ninth embodiment of the present invention. In this embodiment, the structure of the B4-flash memory device is similar to that in the first, fifth, sixth and seventh embodiments, except that n⁻ semiconductor substrates 1 of the first, fifth, sixth and seventh embodiments are replaced with p⁻ semiconductor substrate 901, p⁺ source region 2, drain region 3 and impurity diffusion region 4 are replaced with n⁺ source region 902, drain region 903 and impurity diffusion region 904. In addition, the structure of the B4-flash memory device of this embodiment is similar to that in the first, fifth, sixth and seventh embodiments, except that source region 902 is grounded (Vₛ=0V), the voltage V_{d}=+1.8V is applied to drain region 903, the voltage V_{cg}=12V is applied to control gate 9, the voltage V_{sub}=−4V is applied to semiconductor substrate 901, wherein the applied voltage V_{cg} is greater than both the voltages Vₛ and V_{d}, and the V_{sub} is smaller than both the voltages Vₛ and V_{d}.

The manufacturing process of the B4-flash memory device of this embodiment is similar to that in the first, fifth, sixth and seventh embodiments, except that semiconductor substrate 901 is formed by p⁻ silicon substrate, and n⁺ impurity such as phosphorus (P) is ion-implanted into source region 902, drain region 903 and impurity diffusion region 904.

In this embodiment, the similar effect may be obtained as in the first, fifth, sixth and seventh embodiments.

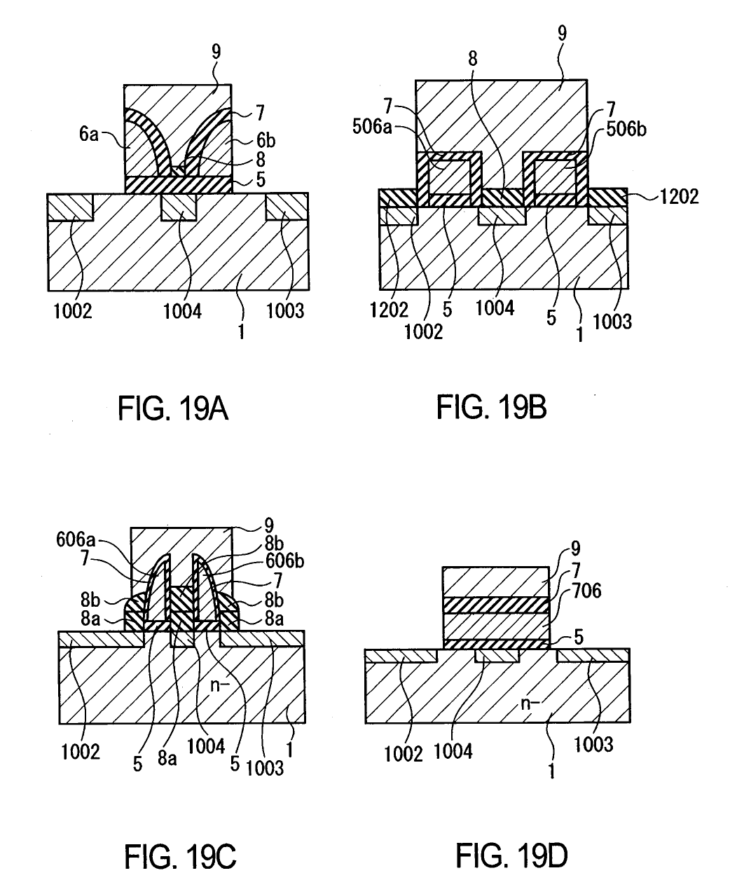

FIGS. 19A-D are cross-sectional views of a B4-flash memory device according to a tenth embodiment of the present invention. In this embodiment, the structure of the B4-flash memory device is similar to that in the first, fifth, sixth and seventh embodiments, except that source region 2, drain region 3 and impurity diffusion region 4, in which impurity is implanted, are formed as conductive regions 1002, 1003 and 1004, in which metal is contained. Conductive regions 1002, 1003 and 1004 containing metal may be formed by, for example, metal and metal silicide. The metal silicide may be formed by, for example, nickel silicide or cobalt silicide. In this embodiment, one of source region 2, drain region 3 and impurity diffusion region 4 may be replaced with the conductive region containing metal.

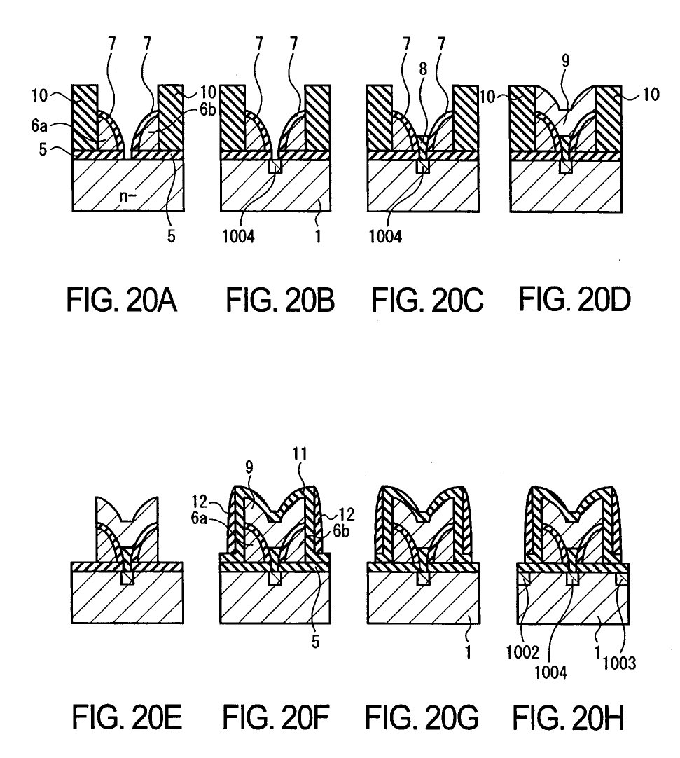

With reference to FIGS. 20A-H, a manufacturing process of the B4-flash memory of FIG. 19A will be explained. FIGS. 20A-H are cross-sectional views of the B4-flash memory of FIG. 19A fabricated according to this embodiment of a method in accordance with the present invention.

As shown in FIG. 20A, first gate insulating film 5 is formed on an entire upper surface of semiconductor substrate 1 such as an n⁻ silicon (Si) substrate 1. First insulating film pattern 10 is formed to cover first gate insulating film 5 on regions where conductive region 1002 containing metal, which is used as the source region, and conductive region 1003 containing metal, which is used as the drain region, and to form expose first gate insulating film 5 under regions where first and second floating gates 6a and 6b will be formed and on a region where impurity diffusion region 1004 will be formed. First insulating film pattern 10 may be an insulating film having an etching selectivity different from first gate insulating film 5 such as a silicon nitride film

A polycrystalline silicon film is deposited by a CVD method. Fan-like first and second floating gates 6a and 6b are then formed respectively on first gate insulating film 5 by etching the polycrystalline silicon film. The sidewalls of first and second floating gates 6a and 6b are formed to be in contact with the inner wall of first insulating film pattern 10 so as to sandwich the region where impurity diffusion region 1004 containing metal will be formed.

First gate insulating film 5 sandwiched between first and second floating gates 6a and 6b are removed to expose the surface of n⁻ silicon (Si) substrate 1 by etching first gate insulating film 5 using first and second floating gates 6a and 6b having intermediate gate insulating film 7 and first insulating film pattern 10 as a mask.

As shown in FIG. 20B, nickel is deposited on the exposed surface of n⁻ silicon (Si) substrate 1 by spattering. Conductive region 1004 containing metal with nickel silicide is formed by a thermal process.

As shown in FIG. 20C, an insulating film is formed on intermediate gate insulating film 7 and conductive region 1004 containing metal. Second gate insulating film 8 is formed in a region sandwiched between first and second floating gates 6a and 6b by an etching process. Second gate insulating film 8 may be formed by, for example, a silicon oxide film.

As shown in FIG. 20D, a polycrystalline silicon film is deposited and patterned with photolithography to form control gate 9 on intermediate gate insulating film 7 formed on first and second floating gates 6a and 6b and second gate insulating film 8 located between first and second floating gates 6a and 6b.

As shown in FIG. 20E, first insulating film pattern 10 is removed by an etching process. As shown in FIG. 20F, a gate protection insulating film 11 is formed to cover the stacked gate structure comprising first and second floating gates 6a and 6b and control gate 9. Gate protection insulating film 11 may be formed by, for example, a silicon oxide. A sidewall insulating film 12 is then formed on gate protection insulating film 11 of a sidewall of the stacked gate structure. Sidewall insulating film 12 may be formed by, for example, TEOS.

As shown in FIG. 20G, the surface of n⁻ silicon substrate 1 is exposed by etching gate protection insulating film 11 exposed outside of sidewall insulating film 12 and first gate insulating film 5 using the stacked structure as a mask.

As shown in FIG. 20H, nickel is deposited on the exposed surface of n⁻ silicon (Si) substrate 1 by spattering. Conductive region 1002 containing metal, which is used as a source region comprising nickel silicide and conductive region 1003 containing metal, which is used as a drain region are then formed respectively. The B4-flash memory as shown in FIG. 19A is fabricated by the above manufacturing process.

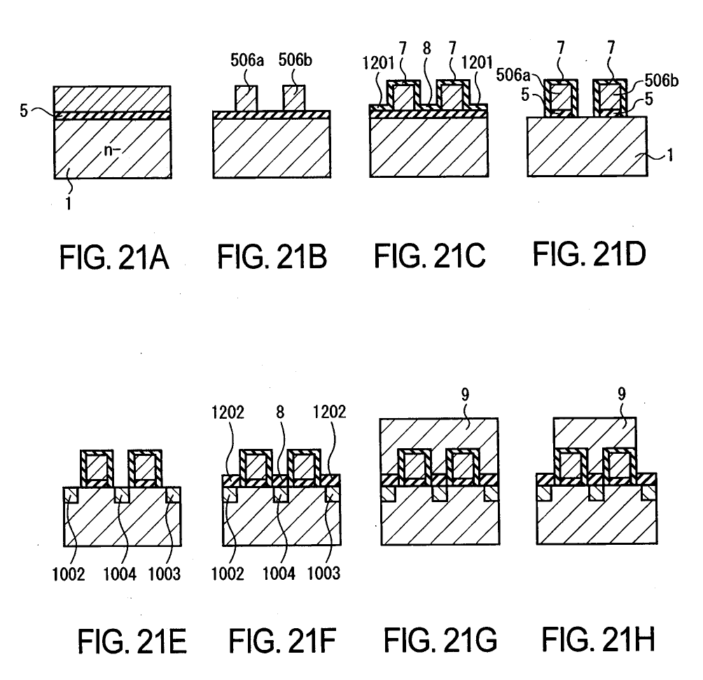

With reference to FIGS. 21A-H, a manufacturing process of the B4-flash memory of FIG. 19B will be explained. FIGS. 21A-H are cross-sectional views of the B4-flash memory of FIG. 19B fabricated according to this embodiment of a method in accordance with the present invention.

As shown in FIG. 21A, first gate insulating film 5 such as a silicon oxide film is formed on an entire upper surface of an n⁻ silicon (Si) substrate 1. A polycrystalline silicon is deposited on an entire upper surface of first gate insulating film 5. As shown in FIG. 21B, the polycrystalline silicon is then patterned by photolithography to form first and second floating gates 506a and 506b having the rectangular shape. First and second floating gates 506a and 506b are formed to expose first gate insulating film 5 on regions where conductive region 1002 containing metal, which is used as the source region, conductive region 1003 containing metal, which is used as the drain region, and conductive region 1004 containing metal will be formed.

As shown in FIG. 21C, an ONO film is deposited on first gate insulating film 5 having first and second floating gates 506a and 506b by a CVD method. As shown in FIG. 21D, the ONO film on the top and the side of first and second floating gates 506a and 506b is not removed, while the other first gate insulating film 5 and insulating film 1201 are removed by an etching process to expose n⁻ silicon (Si) substrate 1 outside of and between first and second floating gates 506a and 506b. The ONO film formed on the top and the inner side surface of first and second floating gates 506a and 506b will be intermediate gate insulating film 7.

As shown in FIG. 21E, nickel is deposited on the exposed surface of n⁻ silicon (Si) substrate 1 by spattering and is heated. As a result, conductive region 1002 containing metal, which is used as the source region on the left side of first floating gates 506a, conductive region 1004 containing metal located between first and second floating gates 506a and 506b, and conductive region 1003 containing metal, which is used as the drain region on the right side of second floating gates 506b. These conductive regions comprise nickel silicide are formed, respectively. Conductive region 1002, 1003 and 1004 containing metal are formed by nickel silicide.

As shown in FIG. 21F, second gate insulating film 8 is formed on conductive region 1004 containing metal, and insulating film 1202 is formed on conductive regions 1002 and 1003 containing metal, respectively. Second gate insulating film 8 and insulating film 1202 may be an insulating film such as a silicon oxide film having an etching selectivity different from intermediate gate insulating film 7.

As shown in FIG. 21G, a polycrystalline silicon is deposited on second gate insulating film 8 and insulating film 1202 and intermediate gate insulating film 7. As shown in FIG. 21H, the polycrystalline silicon is then patterned by photolithography to form control gate 9 on first and second floating gates 506a and 506b through intermediate gate insulating film 7 and second gate insulating film 8 located between first and second floating gates 506a and 506b. The B4-flash memory as shown in FIG. 19B is fabricated by the above manufacturing process.

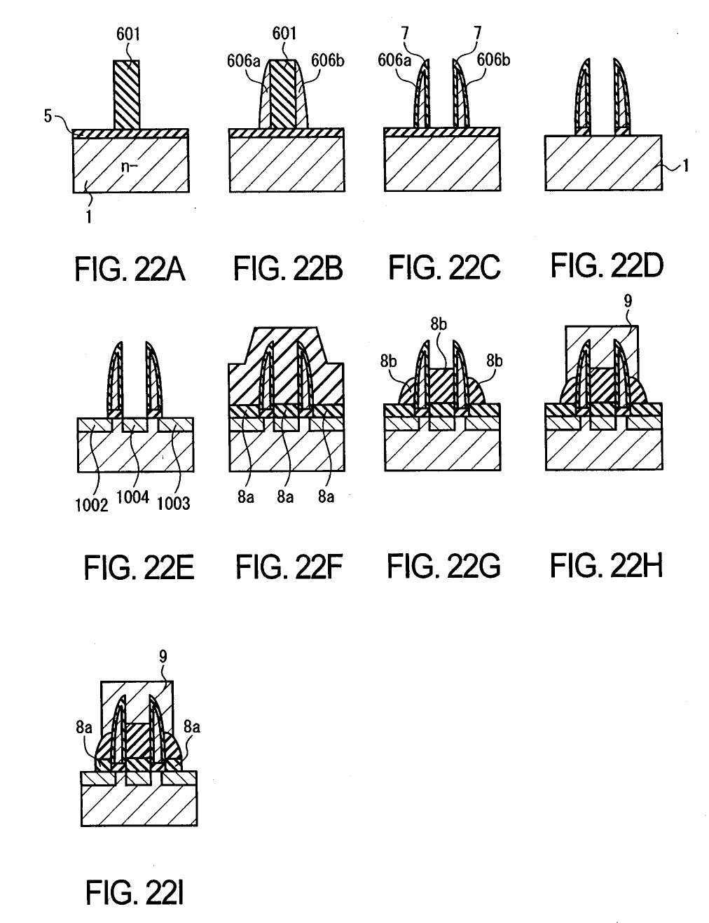

With reference to FIGS. 22A-I, a manufacturing process of the B4-flash memory of FIG. 19C will be explained. FIGS. 22A-I are cross-sectional views of the B4-flash memory of FIG. 19C fabricated according to this embodiment of a method in accordance with the present invention.

As shown in FIG. 22A, first gate insulating film 5 such as a silicon oxide film is formed on an entire upper surface of an n⁻ silicon (Si) substrate 1. Second insulating film pattern 601 in a rectangular form is then formed on first gate insulating film 5 on a region where conductive region 1004 containing metal will be formed. Second insulating film pattern 601 may be a silicon nitride. A polycrystalline silicon is deposited on first gate insulating film 5 to cover second insulating film pattern 601. As shown in FIG. 22B, fan-like first and second floating gates 606a and 606b are then respectively formed to in contact with the both sidewalls of second insulating film pattern 601 by an etching process.

As shown in FIG. 22C, second insulating film pattern 601 is removed by an etching process. Intermediate gate insulating film 7 is formed on the top and the inner side surface of first and second floating gates 606a and 606b by, for example, oxidation and deposition. Intermediate gate insulating film 7 may be, for example, an ONO film.

As shown in FIG. 22D, n⁻ silicon (Si) substrate 1 located outside of first and second floating gates 606a and 606b and between first and second floating gates 606a and 606b is exposed by etching first gate insulating film 5 using first and second floating gates 606a and 606b having intermediate gate insulating film 7 as a mask.

As shown in FIG. 22E, nickel is deposited on the exposed surface of n⁻ silicon (Si) substrate 1 by spattering and heated. As a result, conductive region 1002 containing metal, which is used as the source region on the left side of first floating gates 606a, conductive region 1004 containing metal located between first and second floating gates 606a and 606b, and conductive region 1003 containing metal, which is used as the drain region on the right side of second floating gates 606b. These conductive regions containing metal comprise nickel silicide.

As shown in FIG. 22F, second gate insulating film 8a comprising, for example, a silicon oxide, is fabricated on conductive regions 1002, 1003 and 1004 containing metal to form insulating film 602 on second gate insulating film 8a and intermediate gate insulating film 7. Insulating film 602 may be formed by, for example, a silicon nitride.

As shown in FIG. 22G, second gate insulating film 8b is formed in a region sandwiched between first and second floating gates 606a and 606b and on the left side of first floating gate 606a and the right side of second floating gate 606b respectively by an etching process.

As shown in FIG. 22H, a polycrystalline silicon is deposited on second gate insulating film 8b and intermediate gate insulating film 7. The polycrystalline silicon is then patterned with photolithography to form control gate 9 on second gate insulating film 8b and intermediate gate insulating film 7. As shown in FIG. 22I, second gate insulating film 8a outside of first and second floating gates 606a and 606b is exposed using control gate 9 and second gate insulating film 8b as a mask.

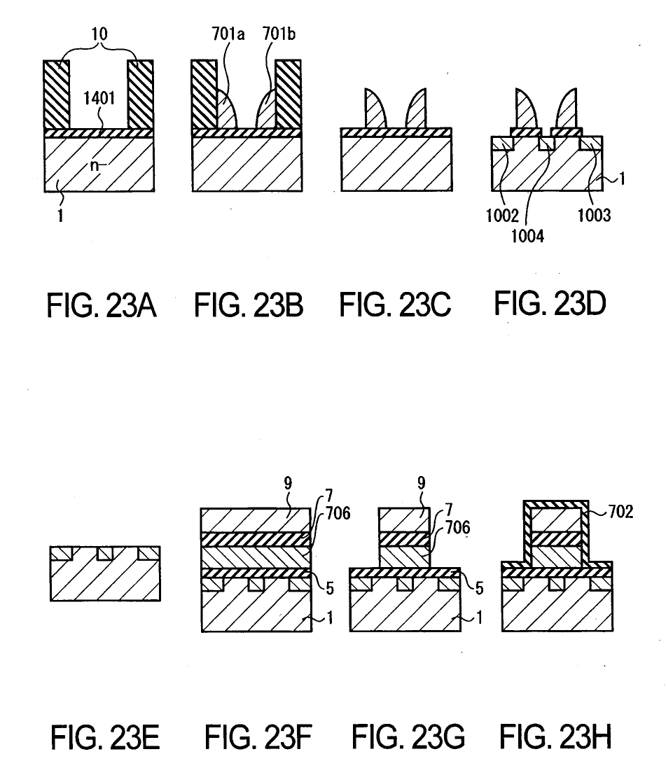

With reference to FIGS. 23A-H, a manufacturing process of the B4-flash memory of FIG. 19D will be explained. FIGS. 23A-H are cross-sectional views of the B4-flash memory of FIG. 19D fabricated according to this embodiment of a method in accordance with the present invention.

As shown in FIG. 23A, insulating film 1401 such as a silicon oxide film is formed on an entire upper surface of n⁻ silicon (Si) substrate 1. First insulating film pattern 10 is formed by, for example, a silicon nitride film to cover insulating film 1401 on regions where conductive regions 1002 and 1003 containing metal will be formed, and to expose insulating film 1401 on a region where impurity diffusion region 1004 will be formed.

As shown in FIG. 23B, a third insulating film pattern 701 is formed on the inner wall of first insulating film pattern 10 and on insulating film 1401. Third insulating film pattern 701 is formed by two insulating film patterns 701a and 701b. Insulating film patterns 701a and 701b are formed in a fan-like form. The sidewalls of insulating film patterns 701a and 701b are formed to be in contact with the sidewalls of first insulating film pattern 10 to sandwich the region where conductive region 1004 containing metal will be formed. Third insulating film pattern 701 may be formed by an insulating film having an etching selectivity different from insulating film 1401 and first insulating pattern 10 (e.g., TEOS).

As shown in FIG. 23C, first insulating film pattern 10 is removed by an etching process. As shown in FIG. 23D, insulating film 1401 is etched to expose n⁻ silicon (Si) substrate 1 located outside of third insulating film pattern 701a and between third insulating film patterns 701a and 701b using third insulating film pattern 701a and 701b as a mask. Nickel is deposited on the exposed surface of n⁻ silicon (Si) substrate 1 by spattering and heated. Conductive region 1002 containing metal, which is used as a source region on the left side of third insulating film pattern 701a, conductive region 1004 containing metal between third insulating film patterns 701a and 701b, and conductive region 1003 containing metal, which is used as a drain region on the right side of third insulating film pattern 701b. These conductive regions containing metal may be formed by nickel silicide.

As shown in FIG. 23E, third insulating film pattern 701 and insulating film 1401 are removed by an etching process. As shown in FIG. 23F, first gate insulating film 5 such as a silicon oxide film, a polycrystalline silicon which will be floating gate 706, an insulating film such as an ONO film which will be intermediate gate insulating film 7, and a polycrystalline silicon which will be control gate 9 are deposited on an entire upper surface of n⁻ silicon (Si) 1 in this sequence.

As shown in FIG. 23G, the stacked gate structure comprising floating gate 706, intermediate gate insulating film 7 and control gate 9 is patterned by photolithography.

As shown in FIG. 23H, gate protection insulating film 702 is formed to cover the surface of the stacked gate structure and exposed first gate insulating film 5. Gate protection insulating film 702 may be formed by, for example, a silicon oxide. The B4-flash memory as shown in FIG. 19D is fabricated by the above manufacturing process.

In this embodiment, the similar effect may be obtained as in the first, fifth, sixth and seventh embodiments. Further, in this embodiment, a Schottky junction is formed, a high electrical field is created and the hot electrons are generated efficiently at the edge of the conductive region containing metal by replacing source region 2, drain region 3 and impurity diffusion region 4 with conductive regions 1002, 1003 and 1004, respectively.

The present invention is not limited to the above first to tenth embodiments. These embodiments may be changed in various ways and may be combined accordingly.

In the above first to tenth embodiments, a semiconductor substrate itself is first conductivity type (i.e., a first conductivity type semiconductor substrate) is explained as the semiconductor substrate having the first conductivity type semiconductor region thereon according to the present invention. However, the semiconductor substrate having the first conductivity type semiconductor region thereon according to the present invention is not limited to the case where a semiconductor substrate itself is first conductivity type. For example, the semiconductor substrate of the present invention includes a structure comprising the first conductivity type semiconductor region formed on the surface of the second conductivity type semiconductor substrate. In the case of an SOI substrate, an SOI layer formed on the surface of the substrate may be the first conductivity type semiconductor layer. That is, the semiconductor substrate having the first conductivity type semiconductor region thereon according to the present invention is a substrate having the first conductivity type semiconductor region thereon.

In the above first to tenth embodiments, the B4-flash memory is explained. However, the present invention is not limited to the B4-flash memory but may be applied to other NOR nonvolatile flash memories.

In the above first to tenth embodiments, impurity diffusion region 4 is set to a floating state. However, impurity diffusion region 4 maybe set to the predetermined potential (e.g., ground potential 0V) by, for example, extending impurity diffusion region 4 to the direction of the channel width direction and arranging the electrode at the extended portion outside the memory cell so as to improve the depletion of impurity diffusion region 4 and the generation rate of the hot electrons due to the band bending. In this case, the potential difference between regions 103 and 102 and between regions 102 and 101 in FIG. 2 become greater, and therefore the electrical fields between regions 103 and 102 and between regions 102 and 101 in FIG. 4 become stronger. As a result, the generation rate of the BBT increases, the number of the hot electrons to be generated increases and the writing efficiency is improved.

It is intended that the shape and the size of the control gate, the floating gate and insulating film or the like be exemplary only, these may be changed within a range not deviated from the scope of the invention. For example, the shaped of the first and second floating gates are shown as a symmetry shape. However, the shaped of the floating gate is not necessarily limited to this shaped to obtain the effect of the present invention.

It is intended that the materials described in the embodiments be exemplary only, other materials may be used within a range not deviated from the scope of the invention.

It is intended that the manufacturing processes described in the embodiments be exemplary only, the order of the manufacturing steps or the like may be changed within a range not deviated from the scope of the invention.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A nonvolatile semiconductor memory device, comprising:
a semiconductor substrate having a first conductivity type semiconductor region on a surface thereof; second conductivity type source and drain regions formed separately from each other in the first conductivity type semiconductor region;
a second conductivity type semiconductor region formed in the first conductivity type semiconductor region arranged between the source and drain regions, the second conductivity type semiconductor region being formed separately from the source and drain regions;
a first gate insulating film formed on the semiconductor substrate arranged between the source and drain regions;
a floating gate formed on the first gate insulating film;
an intermediate gate insulating film formed on the floating gate; and
a control gate formed on the floating gate over the intermediate gate insulating film.

2. A nonvolatile semiconductor memory device, comprising:
a semiconductor substrate having a first conductivity type semiconductor region on a surface thereof;
second conductivity type source and drain regions formed separately from each other in the first conductivity type semiconductor region;
a second conductivity type semiconductor region formed in the first conductivity type semiconductor region arranged between the source and drain regions, the second conductivity type semiconductor region being formed separately from the source and drain regions;
a first gate insulating film formed on the semiconductor substrate arranged between the source and drain regions;
a first floating gate formed between the second conductivity type semiconductor region and the source region over the first gate insulating film;
a second floating gate formed between the second conductivity type semiconductor region and the drain region over the first gate insulating film, the second floating gate being formed separately from the first floating gate;
an intermediate gate insulating film formed on the first and second floating gates; and
a control gate formed on the first and second floating gates over the intermediate gate insulating film and formed on the second conductivity type semiconductor region over the first gate insulating film.

3. A nonvolatile semiconductor memory device, comprising:
a semiconductor substrate having a first conductivity type semiconductor region on a surface thereof;
second conductivity type source and drain regions formed separately from each other in the first conductivity type semiconductor region;
a second conductivity type semiconductor region formed in the first conductivity type semiconductor region arranged between the source and drain regions, the second conductivity type semiconductor region being formed separately from the source and drain regions;
a first gate insulating film formed on the semiconductor substrate arranged between the source and drain regions;
a first floating gate formed between the second conductivity type semiconductor region and the source region over the first gate insulating film;
a second floating gate formed between the second conductivity type semiconductor region and the drain region over the first gate insulating film, the second floating gate being formed separately from the first floating gate;
a first intermediate gate insulating film formed on the first floating gate;
a second intermediate gate insulating film formed on the second floating gate;
a second gate insulating film formed on the first gate insulating film arranged on the second conductivity type semiconductor region; and
a control gate formed on the first and second floating gates over the first and second intermediate gate insulating films and formed on the second conductivity type semiconductor region over the first and second gate insulating films.

4. A nonvolatile semiconductor memory device, comprising:
a semiconductor substrate having a first conductivity type semiconductor region on a surface thereof;
second conductivity type source and drain regions formed separately from each other in the first conductivity type semiconductor region;
a second conductivity type semiconductor region formed in the first conductivity type semiconductor region arranged between the source and drain regions, the second conductivity type semiconductor region being formed separately from the source and drain regions;
a first gate insulating film formed on the semiconductor substrate arranged between the second conductivity type semiconductor region and the source region and between the second conductivity type semiconductor region and the drain region;
a first floating gate formed between the second conductivity type semiconductor region and the source region over the first gate insulating film;
a second floating gate formed between the second conductivity type semiconductor region and the drain region over the first gate insulating film, the second floating gate being formed separately from the first floating gate;
an intermediate gate insulating film formed on the first and second floating gates;
a second gate insulating film formed on the second conductivity type semiconductor region and having a thickness no less than a thickness of the first gate insulating film; and
a control gate formed on the first and second floating gates over the intermediate gate insulating film and formed on the second conductivity type semiconductor region over the second gate insulating film.

5. The memory device according to claim 4, wherein the second gate insulating film has a stacked structure of a plurality of gate insulating films.

6. The memory device according to claim 2, wherein a thickness of each of the first and second floating gates decreases from outside toward inside, and the control gate is formed between the first and second floating gates.

7. The memory device according to claim 2, wherein each of the first and second floating gates has an inner side surface, and the intermediate gate insulating film is formed on the inner side surface, and the control gate is formed between the first and second floating gates over the intermediate gate insulating film.

8. The memory device according to claim 1, wherein the first conductivity type semiconductor region is n type semiconductor, and the source region, the drain region and the second conductivity type semiconductor region are formed from p type semiconductor, and voltages applied to the control gate and the semiconductor substrate is greater than voltages applied to the source and drain regions.

9. The memory device according to claim 1, wherein the first conductivity type semiconductor region is p type semiconductor,
and the source region, the drain region and the second conductivity type semiconductor region are formed from n type semiconductor,
and a voltage applied to the control gate is greater than voltages applied to the source and drain regions, and a voltage applied to the semiconductor substrate is smaller than voltages applied to the source and drain regions.

10. The memory device according to claim 2, wherein the first conductivity type semiconductor region is n type semiconductor,
and the source region, the drain region and the second conductivity type semiconductor region are formed from p type semiconductor,
and voltages applied to the control gate and the semiconductor substrate is greater than voltages applied to the source and drain regions.

11. The memory device according to claim 2, wherein the first conductivity type semiconductor region is p type semiconductor,
and the source region, the drain region and the second conductivity type semiconductor region are formed from n type semiconductor,
and a voltage applied to the control gate is greater than voltages applied to the source and drain regions, and a voltage applied to the semiconductor substrate is smaller than voltages applied to the source and drain regions.

12. The memory device according to claim 3, wherein the first conductivity type semiconductor region is n type semiconductor,
and the source region, the drain region and the second conductivity type semiconductor region are formed from p type semiconductor,
and voltages applied to the control gate and the semiconductor substrate is greater than voltages applied to the source and drain regions.

13. The memory device according to claim 3, wherein the first conductivity type semiconductor region is p type semiconductor,
and the source region, the drain region and the second conductivity type semiconductor region are formed from n type semiconductor,
and a voltage applied to the control gate is greater than voltages applied to the source and drain regions, and a voltage applied to the semiconductor substrate is smaller than voltages applied to the source and drain regions.

14. The memory device according to claim 4, wherein the first conductivity type semiconductor region is n type semiconductor,
and the source region, the drain region and the second conductivity type semiconductor region are formed from p type semiconductor,
and voltages applied to the control gate and the semiconductor substrate is greater than voltages applied to the source and drain regions.

15. The memory device according to claim 4, wherein the first conductivity type semiconductor region is p type semiconductor,
and the source region, the drain region and the second conductivity type semiconductor region are formed from n type semiconductor,
and a voltage applied to the control gate is greater than voltages applied to the source and drain regions, and a voltage applied to the semiconductor substrate is smaller than voltages applied to the source and drain regions.

16. The memory device according to claim 1, wherein the floating gate is replaced with a charge accumulation layer.

17. The memory device according to claim 1, wherein at least one of the source region, the drain region and the second conductivity type semiconductor region is replaced with a conductive region including metal.

18. A method for fabricating a nonvolatile semiconductor memory device, comprising:
forming a first gate insulating film on a semiconductor substrate having a first conductivity type semiconductor region on a surface thereof;
forming first and second gate floating gates to be formed separately from each other on the first gate insulating film;
forming an intermediate gate insulating film formed on the first and second floating gates;
forming a second conductivity type semiconductor region by ion-implanting second conductivity type impurities into the first conductivity type semiconductor region under a region sandwiched between the first and second floating gates using the first and second floating gates with the intermediate gate insulating film as a mask;
forming a control gate on the first and second floating gates over the intermediate gate insulating film and on the second conductivity type semiconductor region over the first gate insulating film; and
forming second conductivity type source and drain regions in the first conductivity type semiconductor region arranged outside of the first and second floating gates.

19. The method according to claim 18, further including forming a second gate insulating film on the first gate insulating film arranged between the first and second floating gates between forming the second conductivity type semiconductor region and forming the control gate.

20. The method according to claim 19, wherein the floating gate is replaced with a charge accumulation layer.
